(19) United States
(12) Patent Application Publication
(10) Pub. No.: US 2014/0003137 A1
(43) Pub. Date: Jan. 2, 2014

(54) DETERMINING DEVICE AND DETERMINING METHOD

(71) Applicant: FUJITSU LIMITED, Kawasaki-shi (JP)

(72) Inventor: Hideyuki Noshiro, Kawasaki (JP)

(73) Assignee: FUJITSU LIMITED, Kawasaki-shi (JP)

(21) Appl. No.: 13/870,301

(22) Filed: Apr. 25, 2013

(30) Foreign Application Priority Data
Jun. 28, 2012 (JP) 2012-146147

(51) Int. Cl. G11C 11/16

(52) U.S. Cl. CPC G11C 11/1673
USPC 365/158

(57) ABSTRACT

A determining device includes: a memory element that includes laminated magnetoresistive elements; reference elements, each having a different resistance value; a select circuit that selects a reference element from the reference elements; an apply circuit that applies a higher read voltage selected from different read voltages to the reference element selected by the select circuit and the memory element, as the resistance value of the reference element selected from the reference elements is higher; a compare circuit that compares an amount of electric current flowing through the selected reference element to which the read voltage is applied by the apply circuit and an amount of electric current flowing through the memory element to which the read voltage is applied by the apply circuit; and a determination circuit that determines data stored in the memory element, based on a result of comparison by the compare circuit.

### CROSS-REFERENCE TO RELATED APPLICATION

This application is based upon and claims the benefit of priority of the prior Japanese Patent Application No. 2012-146147, filed on Jun. 28, 2012, the entire contents of which are incorporated herein by reference.

### FIELD

The embodiments discussed herein are related to a determining device and a determining method.

### BACKGROUND

In the related art, a magnetic random access memory (MRAM) is known in which one memory element stores two values using a magnetoresistive element. Furthermore, the technology is known in which one memory element stores two or more values by causing one memory element to use laminated multiple magnetoresistive elements (for example, refer to Japanese Laid-open Patent Publication No. 2006-203064 and Japanese National Publication of International Patent Application No. 2007-504651). For example, in the case of reading data stored in the memory element, a read voltage is applied to a resistance value of a reference element and a memory element, and it is determined which data is stored in the memory element, by comparing amounts o02f electric current (for example, refer to T. Ishigaki et al, “A Multi-Level-Cell Spin-Transfer Torque Memory with Series-Stacked Magnetotunnel Junctions”, 2010 Symposium on VLSI Technology Digest of Technical Papers: pp. 47-48).

Furthermore, the technology is known in which in a flash memory, erroneous determination of the data stored in the memory element and delay in access time to the corresponding data may be kept from occurring by correcting a physical amount of the corresponding memory element in the case where the physical amount of the memory element is out of a predetermined range (for example, refer to Japanese Laid-open Patent Publication No. 2004-185753).

### SUMMARY

However, in the case where the resistance value of the reference element is high, a likelihood of the erroneous determination of the data is high because a difference in electric current is small between the reference element and the memory element. Furthermore, because the read voltage is high and approaches a rewrite voltage, there is a likelihood that the data stored in the memory element are rewritten.

According to an aspect of the embodiments, a determining device includes: a memory element that includes laminated magnetoresistive elements; reference elements, each having a different resistance value; a select circuit that selects a reference element from the reference elements; an apply circuit that applies a higher read voltage selected from different read voltages to the reference element selected by the select circuit and the memory element, as the resistance value of the reference element selected from the reference elements is higher; a compare circuit that compares an amount of electric current flowing through the selected reference element to which the read voltage is applied by the apply circuit and an amount of electric current flowing through the memory element to which the read voltage is applied by the apply circuit; and a determination circuit that determines data stored in the memory element, based on a result of comparison by the compare circuit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating an example of a determining device according to the present embodiment;

FIG. 2 is a view illustrating a structural example of a horizontal type MTJ element;

FIG. 3 is a view illustrating a second structural example of the vertical type MTJ element;

FIG. 4 is a graph illustrating an example of electric characteristics;

FIG. 5 is a view illustrating an example in which MTJ elements are laminated;

FIGS. 6A to 6J are views, each illustrating an example of a process of making a memory element;

FIG. 7 is a table illustrating a configuration example of the MTJ element;

FIG. 8 is a view illustrating an example of a circuit diagram of the multiple memory elements;

FIG. 9 is a table illustrating a specific example of the determining device;

FIG. 10 is a graph illustrating an example of a resistance distribution in the case where four values are storable;

FIG. 11 is a table illustrating an amount of electric current that flows through each reference element and the memory element in the case where read voltages are the same;

FIG. 12 is a table illustrating a relationship between the read voltage and a reference element;

FIG. 13 is a table illustrating each amount of electric current in the case where a first reference element is selected;

FIG. 14 is a table illustrating each amount of electric current in the case where a second reference element is selected;

FIG. 15 is a table illustrating each amount of electric current in the case where a third reference element is selected;

FIG. 16 is a flow chart illustrating one example of a procedure for the determining processing by the determining device according to a first embodiment;

FIG. 17 is a graph illustrating an example of the resistance distribution in the case where the three values are storable;

FIG. 18 is a flow chart illustrating one example of a procedure for the determining processing by the determining device according to a second embodiment;

FIG. 19 is a flow chart illustrating one example of a procedure for the determining processing by the determining device; and

FIG. 20 is a flow chart illustrating one example of the procedure for the determining processing by the determining device.

### DESCRIPTION OF EMBODIMENTS

Embodiments of a determining device and a determining method according to the present embodiments are described in detail referring to the accompanying drawings.

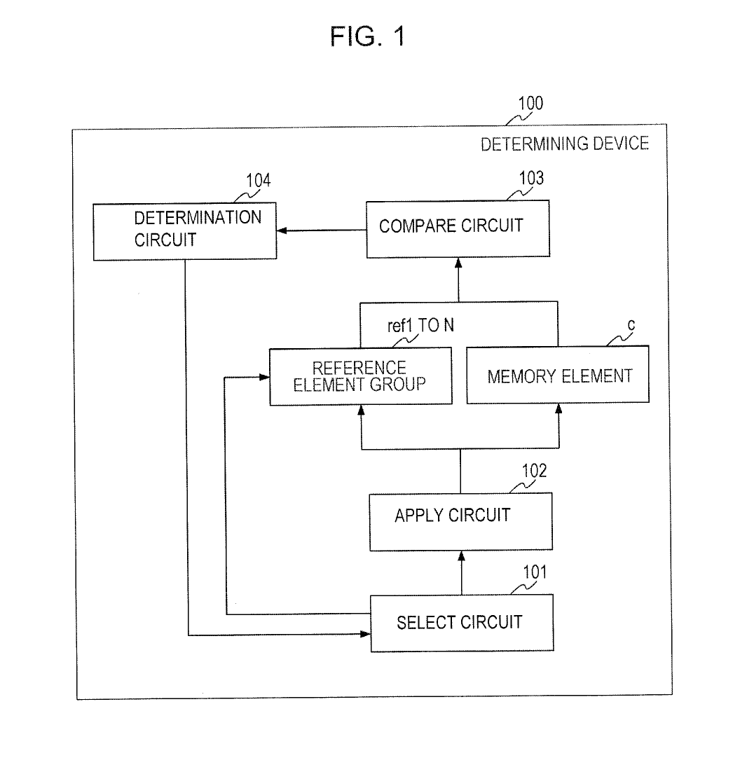

FIG. 1 is a view illustrating the determining device according to the present embodiments. A determining device 100 determines data stored in a memory element c that has laminated magnetoresistive elements. The determining device 100 has multiple reference elements ref1 to refN, each having a different resistance value, a selecting unit 101, an applying unit 102, a comparing unit 103, and a determining unit 104. The selecting unit (select circuit) 101, the applying unit (apply circuit) 102, the comparing unit (compare circuit) 103, and the determining unit (determination circuit) 104, for example, are formed from an OR element, an AND element, a NOT element, a buffer element and others, which are, for example, combinations of a resistor, a capacity, an element such as a transistor, and a transistor. The selecting unit 101, the applying unit 102, the comparing unit 103, and the determining unit 104 may be configured to use a circuit, respectively.

The selecting unit 101 selects one reference element refi (i=1 to N) from the multiple reference elements ref1 to refN. The higher the resistance value of the reference element refs selected from the multiple reference elements ref1 to refN, the higher a read voltage in multiple different read voltages, the applying unit 102 applies to the reference element refs and the memory element c which are selected by the selecting unit 101. At this point, the memory element c to which the applying unit 102 applies the corresponding read voltage is a memory element c selected by address designation from a memory array including multiple memory elements. Each of the multiple different read voltages is a lower voltage than a rewrite voltage, among the voltages at which the read is possible.

The comparing unit 103 compares an amount of electric current flowing through the reference element refi to which the applying unit 102 applies the read voltage and an amount of electric current flowing through the memory element c to which the applying unit 102 applies the read voltage. The determining unit 104 determines the data stored in the memory element c, based on a result of the comparison by the comparing unit 103.

In a case where the resistance value of the reference element refi is high, an erroneous determination rate is high because a difference in electric current is small between the reference element refi and the memory element c. A detailed description with regard to this is provided below. Accordingly, since the higher the resistance value of the reference element refi, the higher the read voltage is increased, the difference in electric current between the reference element refi and the memory element c may be increased, thereby reducing the erroneous determination. On the other hand, since the difference in electric current is small between the reference element refi and the memory element c, in a case where the resistance value of the reference element refi is low, the erroneous determination is lower than in the case where the resistance value of the reference element refi is high. Accordingly, since the lower the resistance value of the reference element ref1, the lower the read voltage is decreased, an occurrence of unintentional rewrite may be suppressed.

Furthermore, the selecting unit 101 selects a reference element refj (j=1 to N, j≠i), which is different from the selected reference element refi, from the multiple reference elements ref1 to refN, in a case where the determining unit 104 is not able to uniquely determine the data stored in the memory element c. Thus, the data stored in the memory element c may be uniquely determined.

In a case of determining the data stored in the memory element c, the selecting unit 101 may first select the lowest reference element of the multiple reference elements ref1 to refN. Even though the read voltage is lower than a write voltage, the higher the voltage, the more likely the data stored in the memory element c is to be rewritten. Furthermore, there is a likelihood that the data is rewritten when applying a high write voltage in a state where electric current does not flow through the memory element c. Accordingly, the unintentional rewrite of the data stored in the memory element c may be suppressed by performing the determination, beginning with the lowest read voltage.

Furthermore, the selecting unit 101 selects the reference element refj, of which the resistance value is low, and which is different from the already-selected reference element refi, from the multiple reference elements ref1 to refN, in a case where the determining unit 104 is not able to uniquely determine the data stored in the memory element c. When a high read voltage is suddenly applied, there is a likelihood that the data stored in the memory element c are rewritten. Accordingly, the unintentional rewrite of the data stored in the memory element c may be suppressed by performing the determination in the order of decreasing the read voltage. Next, a magnetic tunnel junction (MTJ) element and an MRAM are briefly described before providing a detailed description of the determining device 100.

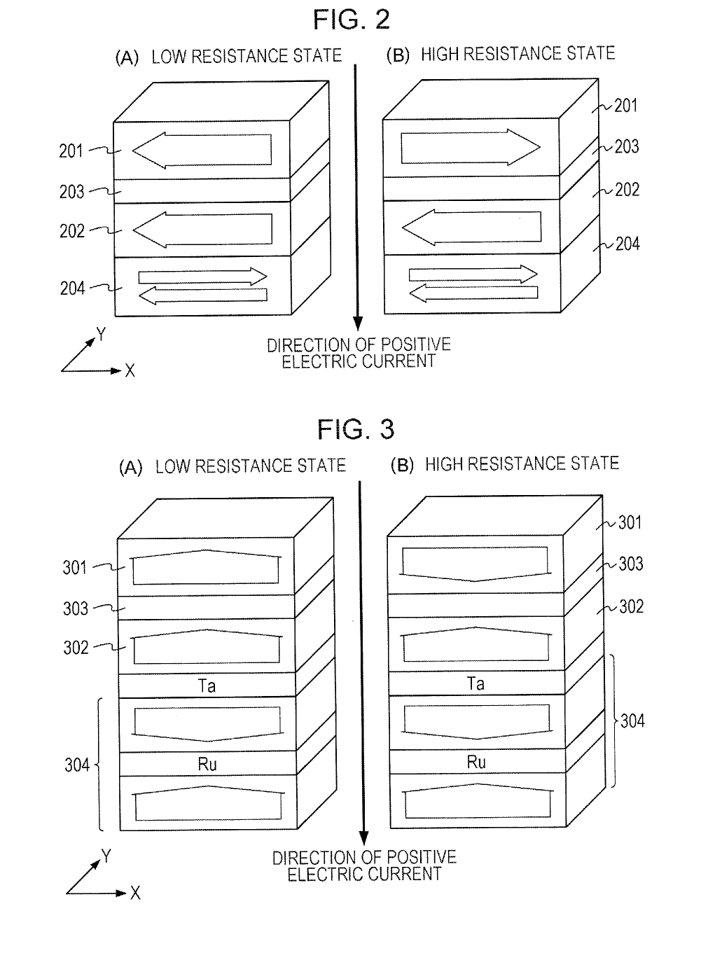

FIG. 2 is a view illustrating a structural example of a horizontal type MTJ element. The MTJ element has a free layer 201, a fixed layer 202, an insulating layer 203 between the fixed layer 202 and the free layer 201, and an antiferromagnetic layer 204 as a base layer, below the fixed layer 202. In the MTJ element illustrated in FIG. 2, the magnetization direction of each layer is the horizontal direction with respect to an overlap of the layers. The magnetic direction of the fixed layer 202 is fixed. Whether the MTJ element is in a high resistance state, or in a low resistance state is determined depending on whether the magnetization direction of the free layer 201 is the same as, or in reverse with respect to the magnetic direction of the fixed layer 202. Information on two values may be stored depending on whether the MTJ element is in the high resistance state, or in the low resistance state. The determination of the high resistance state and the low resistance state depending on the magnetic direction is referred to as a tunnel magneto-resistance (TMR) effect. In a case where the magnetization direction of the free layer 201 is the same as the magnetization direction of the fixed layer 202, the MTJ element is in the low resistance state, and in a case where the magnetization direction of the free layer 201 is in reverse with respect to the magnetization direction of the fixed layer 202, the MTJ element is in the high resistance state. Furthermore, the antiferromagnetic layer 204 has layers in both directions, a layer in the magnetization direction in reverse with respect to the magnetization direction of the fixed layer 202, and a layer in the magnetization direction, the same as the magnetization direction of the fixed layer 202. Thus, the magnetization direction of the antiferromagnetic layer 204 as a whole is set to zero. The magnetization direction underneath the fixed layer 202 in the antiferromagnetic layer 204 is in reverse with respect to the magnetization direction of the fixed layer 202.

FIG. 3 is a view illustrating a second structural example of a vertical type MTJ element. The MTJ element has a free layer 301, a fixed layer 302, and an insulating layer 303 between the fixed layer 302 and a free layer 301, an antiferromagnetic layer 304 as a base layer, below the fixed layer 302. In the MTJ element illustrated, the magnetization direction of each layer is the vertical direction with respect to an overlap of the layers. The MTJ illustrated in FIG. 3 has two states, the low resistance state and the high resistance state according to the magnetization direction of the free layer 301, as the MTJ element illustrated in FIG. 2. Thus, the MTJ element may store two values. Furthermore, the antiferromagnetic layer 304 is called a synthetic antiferromagnetism layer (SAF) because it is made by synthesizing layers. For example, the antiferromagnetic layer 304 is formed by combining two layers that are opposite in magnetization direction, via a Ru layer formed from Ru, a vertical magnetic material. A Ta layer is a layer for the antiferromagnetic layer 304 to block magnetic influence from the fixed layer 302. The magnetization direction of a layer underneath the Ta layer in the antiferromagnetic layer 304 is in reverse with respect to the magnetization direction of the fixed layer 302.

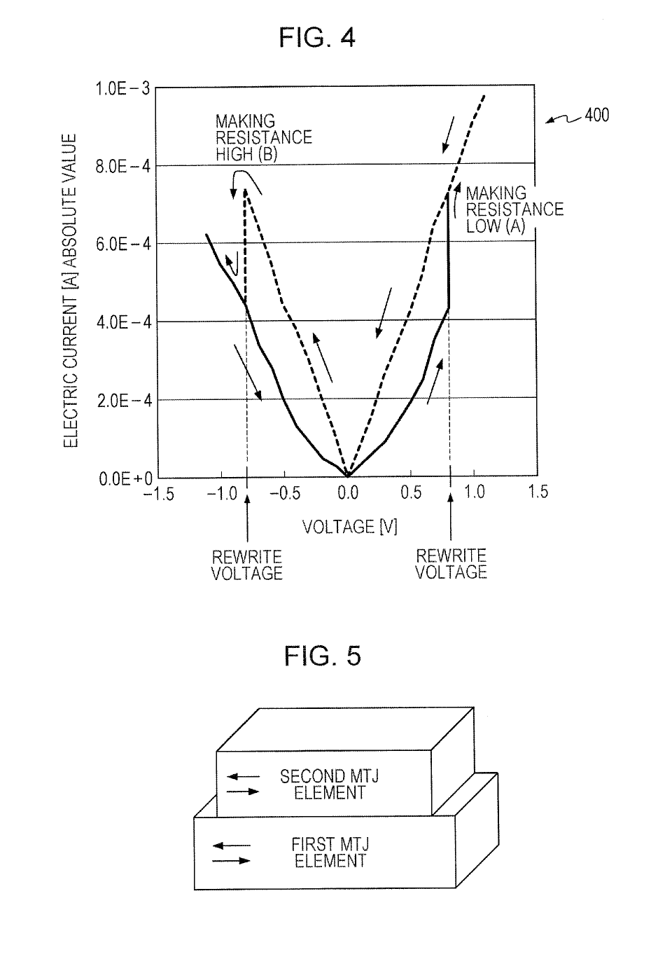

FIG. 4 is a graph illustrating an example of electric characteristics. In the graph 400, the horizontal axis indicates a voltage value and the vertical axis indicates the electric characteristic of the MTJ element that is an absolute value of electric current. The MTJ element is made to be of low resistance (A) when positive electric current flows from the high resistance state, but remains in the high resistance state even though negative electric current flows from the high resistance state. On the other hand, the MTJ element remains in the low resistance state when the positive electric current flows from the low resistance state, but is made to be of high resistance (B) when the negative electric current flows from the low resistance state.

The reference element determines whether the memory element is in the high resistance state or in the low resistance state. For example, the reference element may be the MTJ element as well. The information on two values are stored using a phenomenon that the MTJ element is in the low resistance state and in the high resistance state when the magnetization direction is parallel or antiparallel, but a middle resistance value may not be obtained with one MRJ element. Accordingly, three or more of the resistance states are realized by laminating the MTJ elements.

FIG. 5 is a view illustrating an example in which the MTJ elements are laminated. For example, the resistance state of the laminated MTJ elements as a whole are expressed as the resistance state of a second MTJ element and the resistance state of a first MTJ element. For example, L/L indicates that the second MTJ element is in the low resistance state and the first MTJ element is in the low resistance state. L/H indicates that the second MTJ element is in the low resistance state, and the first MTJ element is in the high resistance state. H/L indicates that the second MTJ element is in the high resistance state, and the first MTJ element is in the low resistance state. H/H indicates that the second MTJ element is in the high resistance state, and the first MTJ element is in the high resistance state. The memory element may store the information on four values by laminating two MTJ elements.

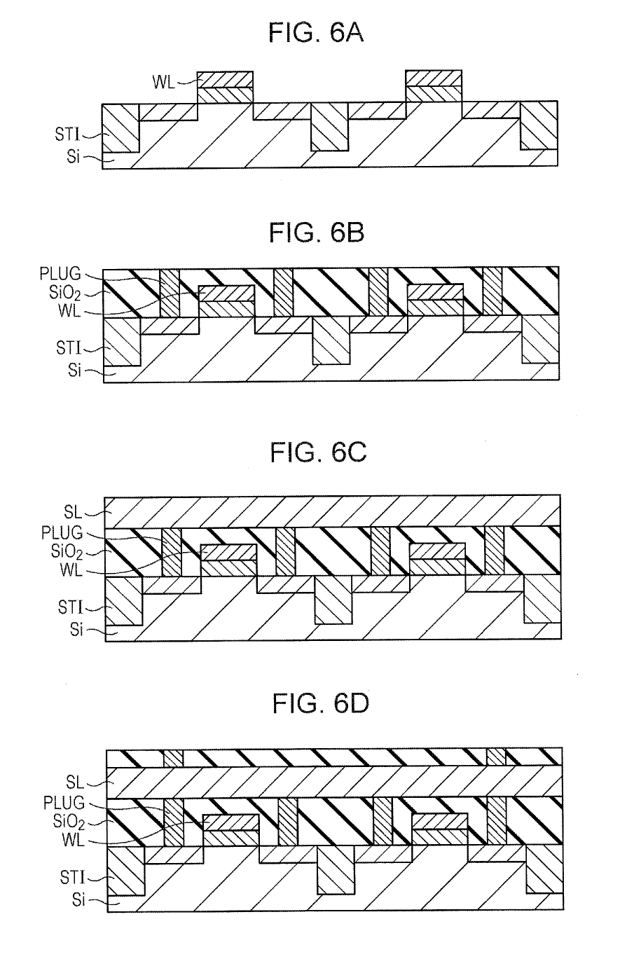

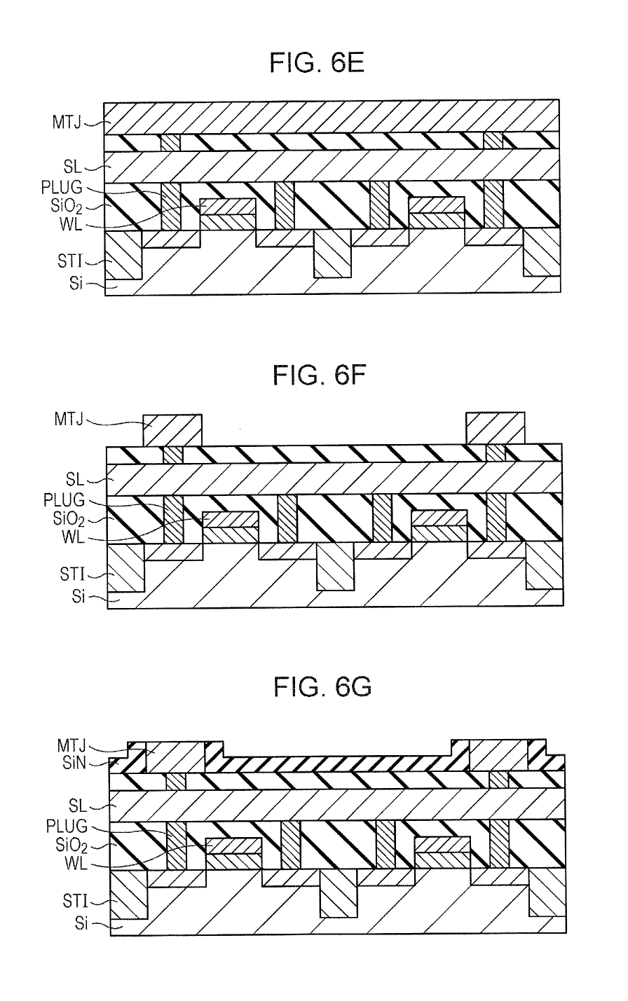

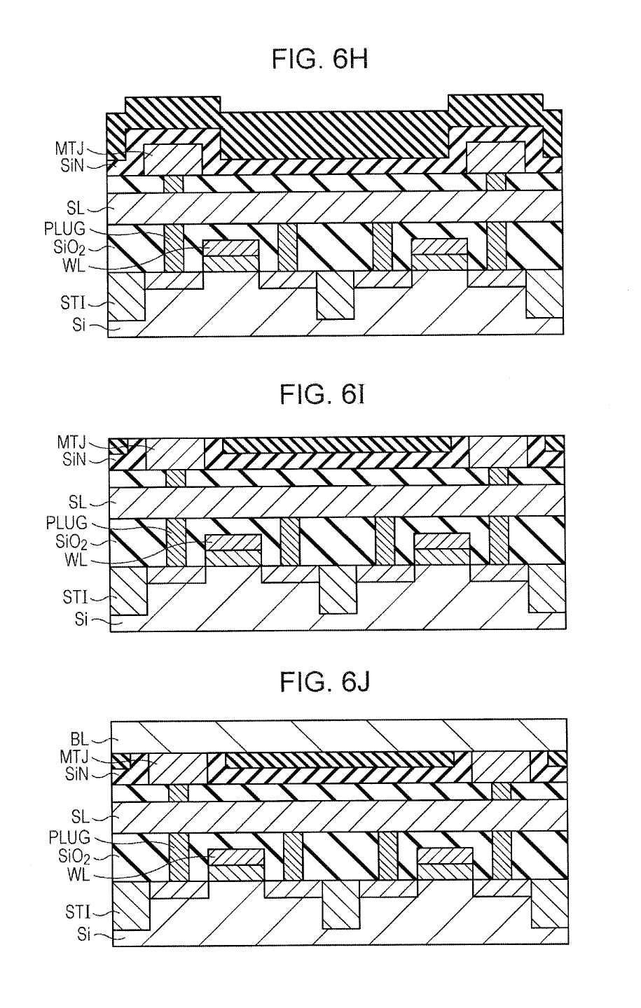

FIGS. 6A to 6J are views, each illustrating an example of a process of making the memory element. A shallow trench isolation (STI) layer is formed on a silicon substrate. The transistor is formed by using a method of making a typical MOS transistor (Refer to FIG. 6A).

A silicon oxide film (an interlayer insulating film) is deposited on a transistor, for example, on a chemical vapor deposition (CVD) layer. A contact hole, which comes into contact with a source (drain) region in the interlayer insulating film, is formed using a photo lithography method and a dry etching method. Next, a titanium nitride (TiN) film as a barrier metal and a tungsten (W) film are deposited using a sputtering method or a CVD method, and thereafter, a contact plug, which electrically connects to the source (drain) region, is formed by burying these conductive films in the contact hole using a chemical mechanical polishing (CMP) method (Refer to FIG. 6B).

The conductive film (for example, aluminum Al and copper Cu) is deposited on the interlayer insulating film in which the conduct plug is buried and an electric connection to the source (drain) region is made via the contact plug using the photolithography method and the dry etching method (formation of a source line (SL) (refer to FIG. 6C)).

A silicon oxide (interlayer insulating film) is deposited on the SL, for example, on the CVD layer. The contact hole, which comes into contact with the source (drain) region in the interlayer insulating film, is formed using the photolithography method and the dry etching method. Next, a titanium nitride (TiN) film as the barrier metal and a tungsten (W) film are deposited using the sputtering method or the CVD method, and thereafter, the electrically-connected contact plug, is formed by burying these conductive films in the contact hole using the CMP method (Refer to FIG. 6D).

Next, a process of making an MRAM element follows. A film formation is performed from a lower electrode to an upper electrode using the sputtering method (refer to FIG. 6E).

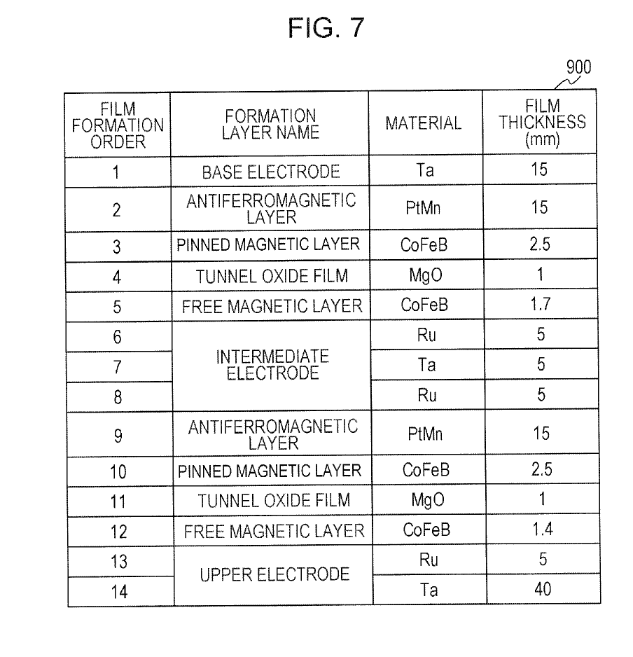

FIG. 7 is a table illustrating a configuration example of the MTJ element. In table 900, film formation orders, formation layer names, materials, and film thicknesses are described. A middle electrode is provided to block a magnetization influence from each MTJ element (to block a magnetic field). The magnetization direction of the memory element is made uniform by performing heat treatment (300° C. to 350° C.) in a magnetic field (for example, 1T) after the film formation.

The element is formed by performing the processing using a patterning (exposure) method and a dry etching method. The laminated MTJ elements may be processed collectively or may be individually processed in a tiered stand (refer to FIG. 6F).

Because magnetic material such as iron (Fe) is used in making the memory element, and thus the memory element is susceptible to oxidization (=rust) at the time of forming the interlayer insulating film, a cover film, such as a silicon nitride (SiN) film is formed to protect the memory element against that phenomenon, using the CVD method and the sputtering method. The film thickness is approximately in a range from 20 to 50 nm (refer to FIG. 6G).

The interlayer insulating film is deposited (refer to FIG. 6H) and is flattened using the CMP method (refer to FIG. 6I). Next, the titanium nitride (TiN) film as the barrier metal and the tungsten (W) film are deposited using the sputtering method and the CVD method, and a wire layer (bit line (BL)) is formed using the patterning (exposure) method and the drying etching method (refer to FIG. 6J).

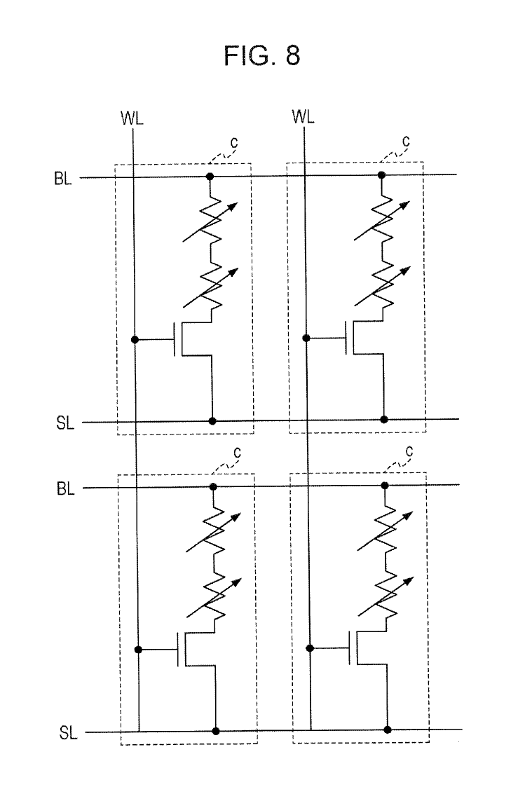

FIG. 8 is a view illustrating an example of a circuit diagram of the multiple memory elements. In FIG. 8, the MTJ element is expressed as a resistor with the arrow attached thereto. The memory element c illustrated in FIG. 8 has two MD elements and transistors, which are enclosed by a dotted-line frame. The memory element c illustrated in FIG. 8 may store a maximum of 4 values. The transistor is provided for selection of each MTJ. It is illustrated that two MTJ elements are laminated as two layers.

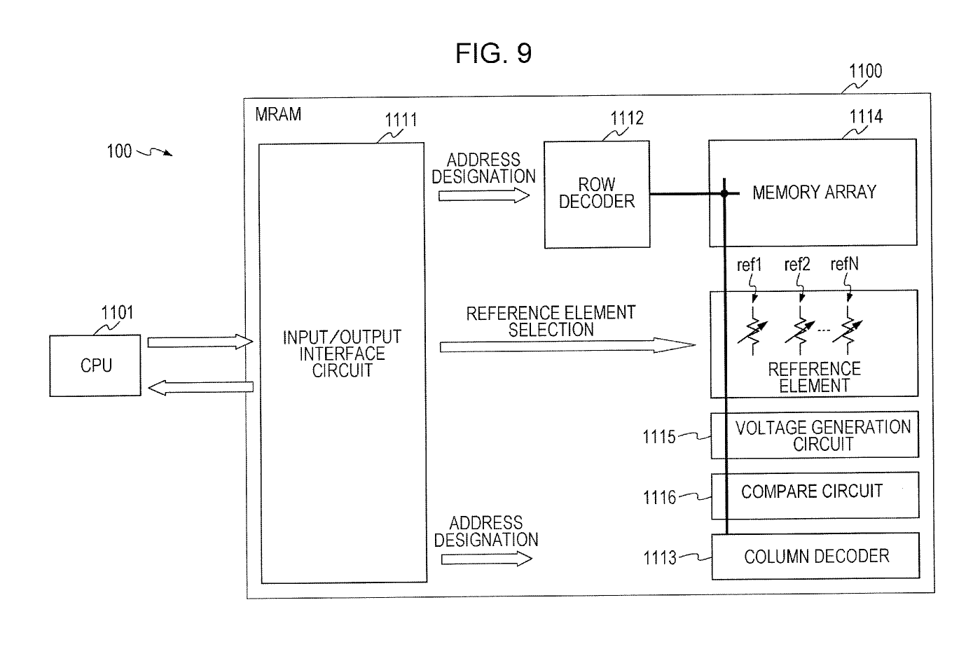

FIG. 9 is a table illustrating a specific example of the determining device. The determining device 100 has a CPU 1101, and an MRAM 1100. For example, the MRAM 1100 has an input/output interface circuit 1111, a row decoder 1112, a column decoder 1113, a memory array 1114, multiple reference elements ref1 to refN, a voltage generation circuit 1115, and a compare circuit 1116.

Each of the multiple reference elements ref1 to refN has a different resistance value, for example, the MTJ element. The input/output interface circuit 1111 receives data such as a read request and a write request from the CPU 1101, or outputs data to the CPU 1101. The CPU 1101 inputs the read request or the write request to the input/output interface circuit 1111. At the time of requesting the read, the CPU 1101 performs address designation and reference element selection. The selecting unit 101 and the determining unit 104, which are described above, for example, are realized by the CPU 1101.

The row decoder 1112 selects a word line, based on a row address designated by the CPU 1101. The column decoder 1113 selects a bit line, based on a column address designated by the CPU 1101.

At the time of requesting the read, the voltage generation circuit 1115 generates a read voltage corresponding to the reference element ref selected by the CPU 1101, and applies the read voltage to the reference element ref selected by the CPU 1101 and the memory element c selected by the column decoder 1113. The applying unit 102 described above, for example, is realized by the voltage generation circuit 1115.

The compare circuit 1116 compares an amount of electric current flowing through the reference element ref to which the read voltage is applied and an amount of electric current flowing through the memory element c to which the read voltage is applied. The comparing unit 103 described above, for example, is realized by the compare circuit 1116. The input/output interface circuit 1111 outputs a result of comparison to the CPU 1101.

The CPU 1101 determines the data in the memory element c, based on the result of the comparison by the compare circuit 1116 of the MRAM 1100. And the CPU 1101 inputs an instruction to select the reference element, different from the already-selected reference element, to an input interface, in a case where the data in the memory element c is not able to be uniquely determined.

Furthermore, the selecting unit 101 and the determining unit 104, for example, are realized by the CPU 1101, but this does not impose any limitation and for example, a circuit having functions of the selecting unit 101 and the determining unit 104 may be provided inside the MRAM 1100.

Next, with regard to the memory element c in which the two MTJ elements are laminated, the example of determination in a case where the four values are stored, is illustrated in the first embodiment, but an example of determination in a case where the three values are stored is illustrated in a second embodiment.

In the first embodiment, the determination of the data stored in the memory element c in a case where the memory element c stores the four values is described.

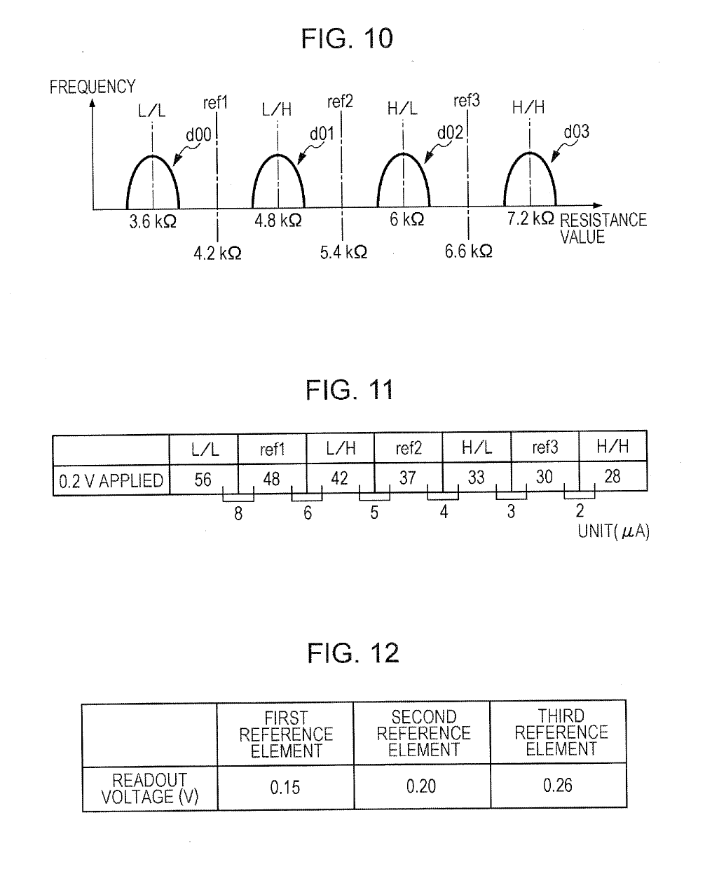

FIG. 10 is a graph illustrating an example of a resistance distribution in a case where the four values are storable. In a case where the memory element c may store the four values, the reference elements are three, and here are defined as first to third reference elements ref1 to ref3. In the resistance distributions d00 to d03, the horizontal axis indicates the resistance value and the vertical axis indicates the number of the memory elements c in the memory array in a case where the corresponding resistance value is present. The resistance value illustrated in FIG. 10, is a resistance value in the highest position in each resistance distribution.

In a case of L/L, according to the resistance distribution d00, the resistance value of the memory element c is 3.6 kΩ), and in a case of L/H, according to the resistance distribution d01, the resistance value of the memory element c is 4.8 kΩ. In a case of H/L, according to the resistance distribution d02, the resistance value of the memory element c is 6 kΩ, and in a case of H/H, according to the resistance distribution d03, the resistance value of the memory element c is 7.2 kΩ. The resistance value of the first reference ref1 is 4.2 kΩ, the resistance value of the second reference ref2 is 5.4 kΩ, and the resistance value of the third reference element ref3 is 6.6 kΩ.

FIG. 11 is a table illustrating an amount of electric current that flows through each REF element and the memory element in a case where the read voltages are the same. In FIG. 11, for example, the amount of electric current is illustrated which flows through each element in a case where the read voltage of 0.2 V is applied to the memory element c and the reference element in each resistance state.

For example, the amount of flowing electric current flowing in a case where the resistance state of the memory element c is L/L is 56 μA, the amount of electric current flowing through the first reference element ref1 is 48 μA and the amount of electric current flowing in a case where the resistance state of the memory element c is L/H is 42 μA. A differential value is 8 μA between the amount of electric current flowing through the first reference element ref1 and the amount of electric current flowing in the case where the resistance state of the memory element c is L/L, and the differential value is 6 μA between the amount of electric current flowing through the first reference element ref1, and the amount of electric current flowing in the case where the resistance state of the memory element c is L/H.

For example, the amount of electric current flowing in a case where the resistance state of the memory element c is L/H is 42 μA, the amount of electric current flowing through the second reference element ref2 is 37 μA and the amount of electric current flowing in a case where the resistance state of the memory element c is H/L is 33 μA. The differential value is 5 μA between the amount of electric current flowing through the second reference element ref2 and the amount of electric current flowing in the case where the resistance state of the memory element c is L/H, and the differential value is 4 μA between the amount of electric current flowing through the second reference element ref2 and the amount of electric current flowing in the case where the resistance state of the memory element c is H/L.

For example, the amount of electric current flowing in a case where the resistance state of the memory element c is H/L is 33 μA, the amount of electric current flowing through the third reference element ref3 is 30 μA, and the amount of electric current flowing in a case where the resistance state of the memory element c is H/H is 28 μA. The differential value is 3 μA between the amount of electric current flowing through the third reference element ref3 and the amount of electric current flowing in the case where the resistance state of the memory element c is H/L, and the differential value is 2 μA between the amount of electric current flowing through the third reference element ref3 and the amount of electric current flowing in the case where the resistance state of the memory element c is H/H.

A likelihood of the erroneous determination is low, because when the resistance value of the reference element is low, the difference is small between the amount of electric current flowing through the memory element c and the amount of electric current flowing through the reference element. On the other hand, the likelihood of the erroneous determination is high, because when the resistance value of the reference element is high, the difference is large between the amount of electric current flowing through the memory element c and the amount of electric current flowing through the reference element. And as illustrated in FIG. 1, the higher the resistance value of the selected reference element, the higher the determining device 100 increases the read voltage.

FIG. 12 is a table illustrating a relationship between the read voltage and the reference element. In the table, the read voltage is described which is applied to the selected reference element and the memory element c that is an object to be read from, according to the selected reference element. The first reference element ref1 is lower in the resistance value than the second reference element ref2, and the second reference element ref2 is lower in the resistance value than the third reference element ref3. For this reason, in a case where the first reference element ref1 is selected, the read voltage is 0.15 V. For example, in a case where the second reference element ref2 is selected, the read voltage is 0.20 V, and in a case where the third reference element ref3 is selected, the read voltage is 0.26 V. Thus, the higher the resistance value of the selected reference element, the higher the read voltage is increased.

When the higher the resistance value of the reference element, the higher the read voltage is increased, the read voltage read by the reference element may not vary from one reference element to another, as illustrated in FIG. 12. For example, the read voltages corresponding to the first reference element ref1 and the second reference element ref2 may be made the same, and the read voltage corresponding to the third reference ref3 may be made a higher voltage than the read voltages corresponding to the first reference element ref1 and the second reference element ref2. Otherwise, for example, the read voltages corresponding to the second reference element ref2 and the third reference element ref3 may be made the same, and the read voltage corresponding to the first reference ref1 may be made a lower voltage than the read voltages corresponding to the second reference element ref2 and the third reference element ref3.

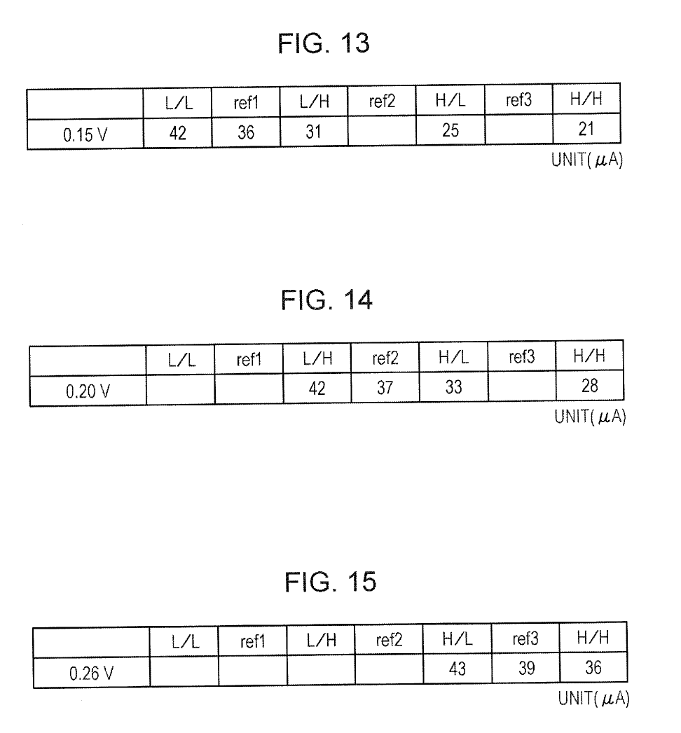

FIG. 13 is a table illustrating each amount of electric current in a case where the first reference element is selected. The determining device 100 selects the reference element of which the resistance value is the lowest from the multiple reference elements ref1 to refN through the use of the selecting unit 101. First of all, the first reference element ref1 is selected. At this point, the lowest read voltage of the multiple read voltages is applied to the memory element c by selecting the reference element of which the resistance value is the lowest. Thus, it is possible that changes in the direction of the memory element c or burnout of the memory element c are kept from occurring.

The determining device 100 applies the read voltage of 0.15 V to the first reference element ref1 and the memory element c that is the object to be read from, through the use of the applying unit 102. The amount of electric current flowing through the first reference element ref1 is 36 μA. The determining device 100 compares the amount of electric current flowing through the first reference element ref1 and the amount of the memory element c through the use of the comparing unit 103. For example, in a case where L/L is stored in the memory element c, the amount of electric current flowing through the memory element c is approximately 42 μA.

The determining device 100 determines that the data stored in the memory element c is L/L, in a case where the amount of electric current flowing through the memory element c is equal to or more than the amount of electric current flowing through the first reference element ref1. On the other hand, the determining device 100 determines that the data stored in the memory element c is not L/L, in a case where the amount of electric current flowing through the memory element c is neither equal to, nor more than the amount of electric current flowing through the first reference element ref1.

FIG. 14 is a table illustrating each amount of electric current in a case where the second reference element is selected. The determining device 100 selects the second reference element ref2 of which the resistance value is the lowest from the unselected reference elements through the use of the selecting unit 101, in a case where it is determined that the data stored in the memory element c is not L/L.

The determining device 100 applies the read voltage of 0.20 V to the second reference element ref2 and the memory element c that is the object to be read from, through the use of the applying unit 102. The amount of electric current flowing through the second reference element ref2 is 37 μA. The determining device 100 compares the amount of electric current flowing through the second reference element ref2 and the amount of the memory element c through the use of the comparing unit 103. For example, in a case where L/H is stored in the memory element c, the amount of electric current flowing through the memory element c is approximately 42 μA.

The determining device 100 determines that the data stored in the memory element c is L/H, in a case where the amount of electric current flowing through the memory element c is equal to or more than the amount of electric current flowing through the second reference element ref2. On the other hand, the determining device 100 determines that the data stored in the memory element c is neither L/L, nor L/H, in a case where the amount of electric current flowing through the memory element c is neither equal to nor more than the amount of electric current flowing through the second reference element ref2.

FIG. 15 is a table illustrating each amount of electric current in a case where the third reference element is selected. The determining device 100 selects the third reference element ref3 of which the resistance value is the lowest from the unselected reference elements through the use of the selecting unit 101, in a case where it is determined that the data stored in the memory element c is neither L/L, nor L/H.

The determining device 100 applies the read voltage of 0.26 V to the third reference element ref3 and the memory element c that is the object to be read from, through the use of the applying unit 102. The amount of electric current flowing through the third reference element ref3 is 39 μA. The determining device 100 compares the amount of electric current flowing through the third reference element ref3 and the amount of the memory element c through the use of the comparing unit 103. For example, in a case where H/L is stored in the memory element c, the amount of electric current flowing through the memory element c is approximately 43 μA.

The determining device 100 determines that the data stored in the memory element c is H/L, in a case where the amount of electric current flowing through the memory element c is equal to or more than the amount of electric current flowing through the third reference element ref3. On the other hand, the determining device 100 determines that the data stored in the memory element c is H/H, in a case where the amount of electric current flowing through the memory element c is neither equal to nor more than the amount of electric current flowing through the third reference element ref3.

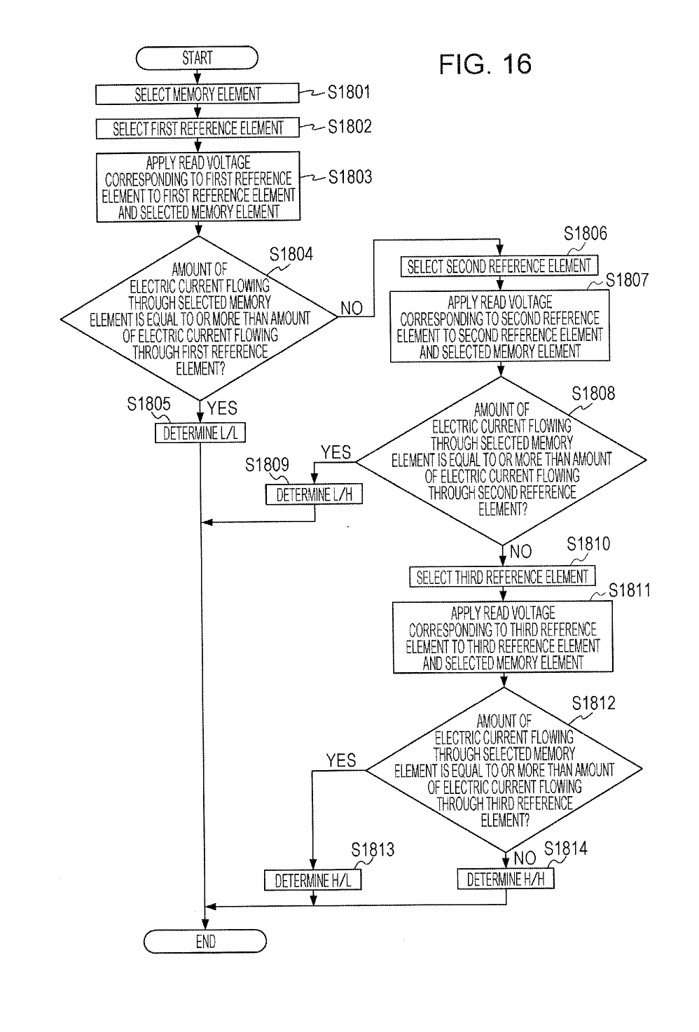

FIG. 16 is a flow chart illustrating one example of a procedure for the determining processing by the determining device according to the first embodiment. The determining device 100 selects the memory element c that is the object to be read from, from the memory array (Step S1801). At this point, the selected memory element c is referred to as a selection memory element c. The determining device 100 selects the first reference element ref1 (Step S1802), and applies the read voltage corresponding to the first reference element ref1 to the first reference element ref1 and the selection memory element c (Step S1803).

The determining device 100 determines whether or not the amount of electric current flowing through the selection memory device c is equal to or more than the amount of electric current flowing through the first reference element ref1 (Step S1804). In a case where the amount of electric current flowing through the selection memory element c is equal to or more than the amount of electric current flowing through the first reference element ref1 (Step S1804: Yes), the determining device 100 determines that the data stored in the memory element is L/L (Step S1805) and ends a processing sequence.

In a case where the amount of electric current flowing through the selection memory element c is neither equal to nor more than the amount of electric current flowing through the first reference element ref1 (Step S1804: No), the determining device 100 selects the second reference element ref2 (Step S1806). The determining device 100 applies the read voltage corresponding to the second reference element ref2 to the second reference element ref2 and the selection memory element c (Step S1807).

The determining device 100 determines whether or not the amount of electric current flowing through the selection memory device c is equal to or more than the amount of electric current flowing through the second reference element ref2 (Step S1808). In a case where the amount of electric current flowing through the selection memory element c is equal to or more than the amount of electric current flowing through the second reference element ref2 (Step S1808: Yes), the determining device 100 determines that the data stored in the memory element is L/H (Step S1809) and ends the processing sequence. In a case where the amount of electric current flowing through the selection memory element c is neither equal to nor more than the amount of electric current flowing through the second reference element ref2 (Step S1808: No), the determining device 100 selects the third reference element ref3 (Step S1810).

The determining device 100 applies the read voltage corresponding to the third reference element ref3 to the third reference element ref3 and the selection memory element c (Step S1811), and determines whether or not the amount of electric current flowing through the selection memory element c is equal to or more than the amount of electric current flowing through the third reference element ref3 (Step S1812). In a case where the amount of electric current flowing through the selection memory element c is equal to or more than the amount of electric current flowing through the third reference element ref3 (Step S1812: Yes), the determining device 100 determines that the data stored in the memory element is H/L (Step S1813) and ends a processing sequence. In a case where the amount of electric current flowing through the selection memory element c is neither equal to nor more than the amount of electric current flowing through the third reference element ref3 (Step S1812: No), the determining device 100 determines that the data stored in the memory element are H/H (Step S1814) and ends a processing sequence.

In the second embodiment, the determination of the data stored in the memory element c in a case where the memory element c stores the three values is described.

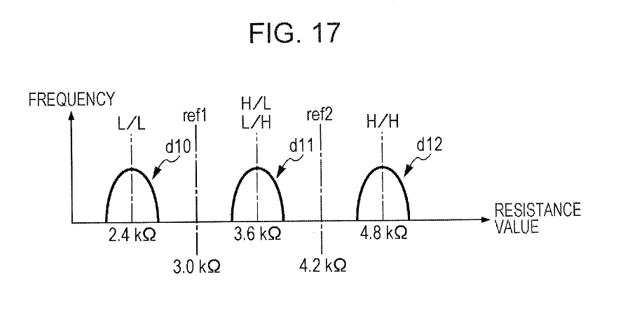

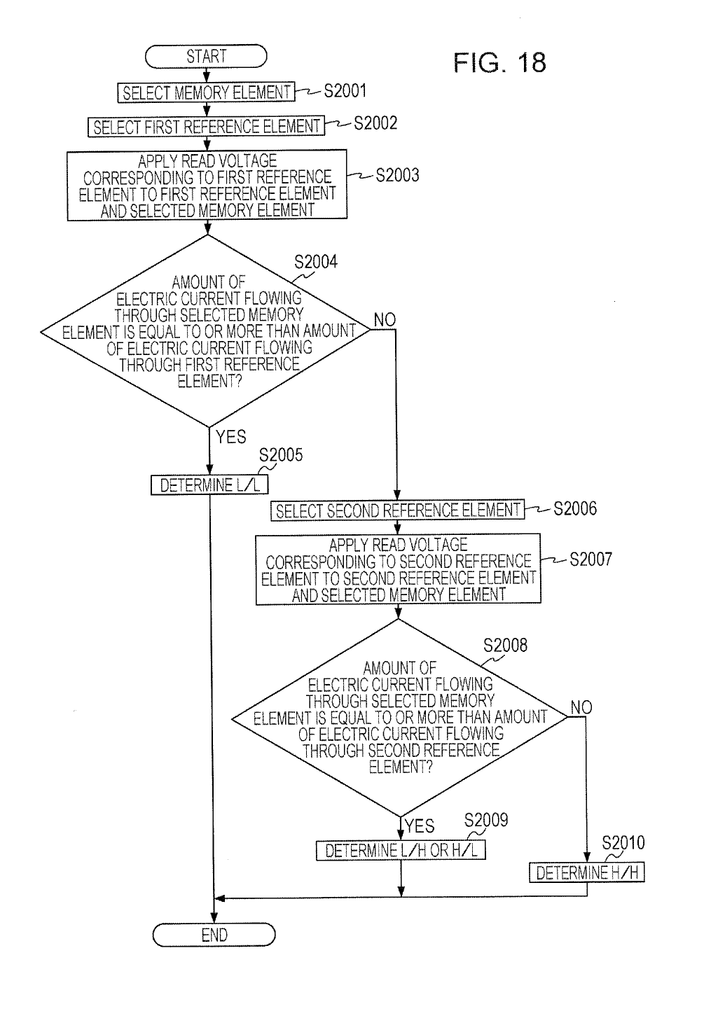

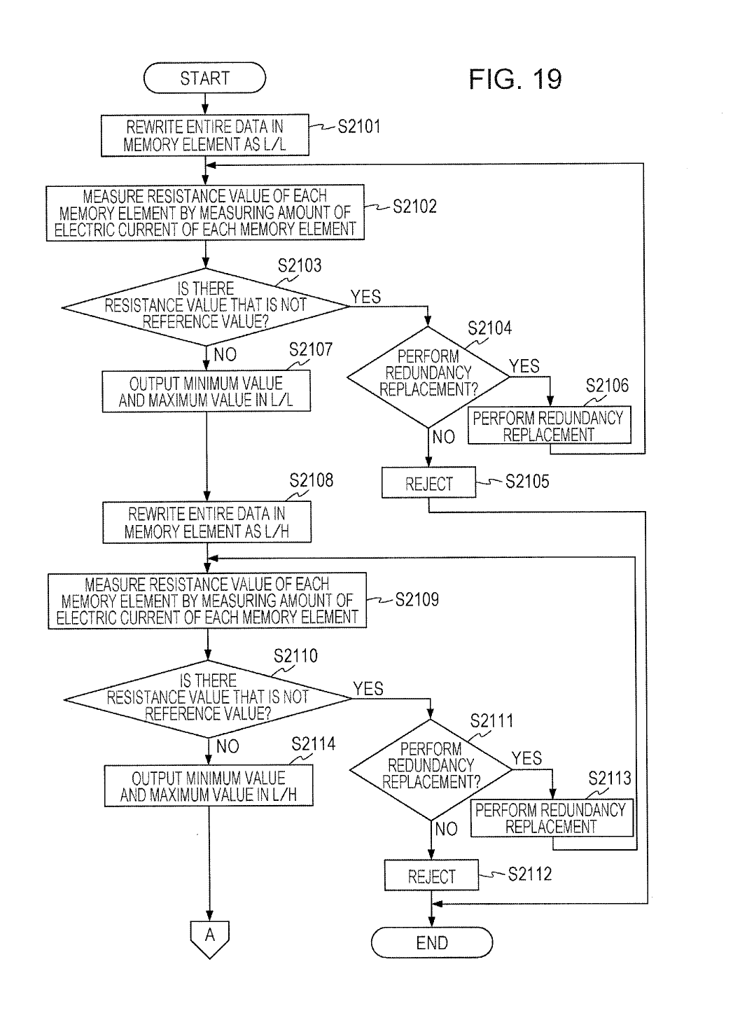

FIG. 17 is a graph illustrating an example of the resistance distribution in a case where the three values are storable. In a case where the memory element c may store the three values, the reference elements are two, and here are defined as the first to second reference elements ref1 and ref2. In the resistance distributions d10 to d12, the horizontal axis indicates the resistance value, and the vertical axis indicates the number of the memory elements c in the memory array in a case where the corresponding resistance value is present. The resistance value illustrated in FIG. 17, is a resistance value in the highest position in the distribution.

In a case of L/L, according to the resistance distribution d10, the resistance value of the memory element c is 2.4 kΩ, and in a case of H/H or H/L, according to the resistance distribution d11, the resistance value of the memory element c is 3.6 kΩ. In a case of H/H, according to the resistance distribution d12, the resistance value of the memory element c is 4.8 kΩ. The resistance value of the first reference element ref1 is 3.0 kΩ, and the resistance value of the second reference element ref2 is 4.2 kΩ. A determination example is described referring to the flow chart illustrated in FIG. 18.

FIG. 18 is a flow chart illustrating one example of a procedure for the determining processing by the determining device according to the second embodiment. The determining device 100 selects the memory element c that is the object to be read from, from the memory array (Step S2001). At this point, the selected memory element c is referred to as a selection memory element c. The determining device 100 selects the first reference element ref1 (Step S2002), and applies the read voltage corresponding to the first reference element ref1 to the first reference element ref1 and the selection memory element c (Step S2003).

The determining device 100 determines whether or not the amount of electric current flowing through the selection memory element c is equal to or more than the amount of electric current flowing through the first reference element ref1 (Step S2004). In a case where the amount of electric current flowing through the selection memory element c is equal to or more than the amount of electric current flowing through the first reference element ref1 (Step S2004: Yes), the determining device 100 determines that the data stored in the memory element are L/L (Step S2005) and ends a processing sequence.

In a case where the amount of electric current flowing through the selection memory element c is neither equal to nor more than the amount of electric current flowing through the first reference element ref1 (Step S2004: No), the determining device 100 selects the second reference element ref2 (Step S2006). The determining device 100 applies the read voltage corresponding to the second reference element ref2 to the second reference element ref2 and the selection memory element c (Step S2007).

The determining device 100 determines whether or not the amount of electric current flowing through the selection memory element c is equal to or more than the amount of electric current flowing through the second reference element ref2 (Step S2008). In a case where the amount of electric current flowing through the selection memory element c is equal to or more than the amount of electric current flowing through the second reference element ref2 (Step S2008: Yes), the determining device 100 determines that the data stored in the memory element is L/H or H/L (Step S2009) and ends the processing sequence. In a case where the amount of electric current flowing through the selection memory element c is neither equal to nor more than the amount of electric current flowing through the second reference element ref2 (Step S2008: No), the determining device 100 determines that the data stored in the memory element are H/H (Step S2010) and ends the processing sequence.

Variations may occur in the resistance distribution. Accordingly, in a third embodiment, an example is described in which the resistance distribution is measured in advance, and each read voltage is set based on the resistance distribution.

For example, the data in the memory element c is rewritten as each of the L/L, L/H, H/L, and H/H states, and the resistance distribution is measured in each state. Next, the read voltage according to each reference element is updated to be a read voltage that becomes an amount of electric current that does not exceed the rewrite electric current, based on the obtained distribution. A specific example is described referring to the flow chart.

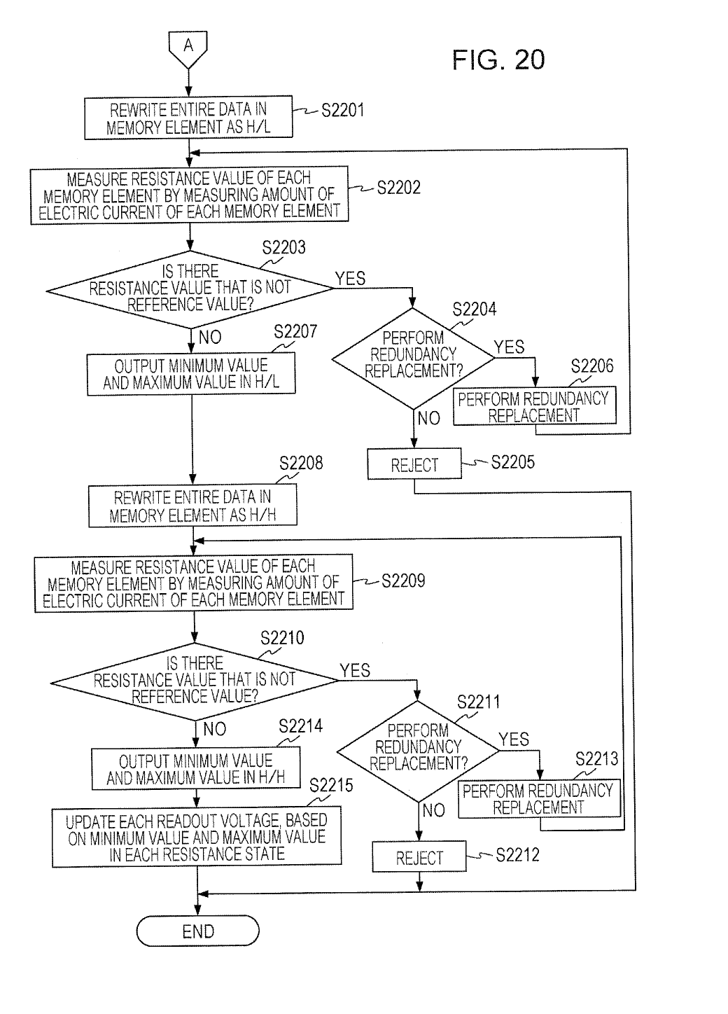

(Example of a setting processing procedure) In FIGS. 19 and 20, one example of the setting processing procedure performed by the determining device is described. First, the determining device 100 rewrites the entire data in the memory element c as L/L (Step S2101), and measures an amount of electric current of each memory element c, thereby measuring the resistance value of the each memory element c (Step S2102).

The determining device 100 determines whether or not an out-of-specification resistance value is present (Step S2103). The out-of-specification resistance value, for example, is a resistance value that is a significantly low resistance value and a significantly high resistance value. Because the memory element c that falls in the range of the out-of-specification resistance value is defective, the determining device 100 determines whether or not to perform redundancy replacement (Step S2104), in a case where the out-of-specification resistance value is present (Step S2103: Yes). For example, the number of the memory elements that fall in the range of the out-of-specification resistance value is greater than the number of the redundancy-replacement-enabled memory elements, it is determined that the redundancy replacement is not performed (Step S2104: No). And the determining device 100 determines that a memory chip is rejected (Step S2105), and ends the processing sequence.

For example, in a case where the number of the memory elements that fall in the range of the out-of-specification resistance value is equal to or smaller than the number of the redundancy-replacement-enabled memory elements, and redundancy restoration is possible, it is determined that the redundancy replacement is performed (Step S2104: Yes). And the determining device 100 performs the redundancy replacement (Step S2106) and returns back to Step S2102. In a case where the out-of-specification resistance value is not present (Step S2103: No), the determining device 100 outputs the minimum value and the maximum value in L/L (Step S2107).

Next, the determining device 100 rewrites the entire data in the memory element c as L/H (Step S2108), and measures an amount of electric current of each memory element c, thereby measuring the resistance value of the each memory element c (Step S2109). The determining device 100 determines whether or not an out-of-specification resistance value is present (Step S2110).

In a case where the out-of-specification resistance value is present (Step S2110: Yes), the determining device 100 determines whether or not to perform the redundancy replacement (Step S2111). For example, the number of the memory elements that fall in the range of the out-of-specification resistance value is greater than the number of the redundancy-replacement-enabled memory elements, it is determined that the redundancy replacement is not performed (Step S2111: No). And the determining device 100 determines that a memory chip is rejected (Step S2112), and ends the processing sequence.

In a case where it is determined that the redundancy replacement is performed (Step S2111: Yes), the determining unit 100 performs the redundancy replacement (Step S2113) and returns back to Step S2109. In a case where the out-of-specification resistance value is not present (Step S2110: No), the determining device 100 outputs the minimum value and the maximum value in L/H (Step S2114) and proceeds to Step S2201. As for an output format for example, the minimum value and the maximum value may be output to a recording device which the CPU 1101 included in the determining device 100 is able to address, instead of to the MRAM that is an object on which to perform the setting processing.

The determining device 100 rewrites the entire data in the memory element c as H/L (Step S2201), and measures an amount of electric current of each memory element c, thereby measuring the resistance value of the each memory element c (Step S2202).

The determining device 100 determines whether or not an out-of-specification resistance value is present (Step S2203). In a case where the out-of-specification resistance value is present (Step S2203: Yes), the determining device 100 determines whether or not to perform the redundancy replacement (Step S2204). In a case where it is determined that the redundancy replacement is not performed (Step S2204: No), the determining device 100 determines that the memory chip is rejected (Step S2205) and ends the processing sequence.

In a case where it is determined that the redundancy replacement is performed (Step S2204: Yes), the determining unit 100 performs the redundancy replacement (Step S2206) and returns back to Step S2202. In a case where the out-of-specification resistance value is not present (Step S2203: No), the determining device 100 outputs the minimum value and the maximum value in H/L (Step S2207).

Next, the determining device 100 rewrites the entire data in the memory element c as H/H (Step S2208), and measures an amount of electric current of each memory element c, thereby measuring the resistance value of the each memory element c (Step S2209). The determining device 100 determines whether or not an out-of-specification resistance value is present (Step S2210).

In a case where the out-of-specification resistance value is present (Step S2210: Yes), the determining device 100 determines whether or not to perform the redundancy replacement (Step S2211). For example, the number of the memory elements that fall in the range of the out-of-specification resistance value is greater than the number of the redundancy-replacement-enabled memory elements, it is determined that the redundancy replacement is not performed (Step S2211: No). And the determining device 100 determines that the memory chip is rejected (Step S2212), and ends the processing sequence.

In a case where it is determined that the redundancy replacement is performed (Step S2211: Yes), the determining unit 100 performs the redundancy replacement (Step S2213) and returns back to Step S2209. In a case where the out-of-specification resistance value is not present (Step S2210: No), the determining device 100 outputs the minimum value and the maximum value in H/H (Step S2214). And the determining device 100 updates each read voltage among the voltages that is lower than the write voltage, based on the minimum value and the maximum value of each resistance state (Step S2215) and ends the processing sequence.

Furthermore, in the first to third embodiments, the memory element in which the two MTJ elements are laminated as two layers is enumerated as an example, but the present embodiments is not limited to this and as long as the lamination is possible, three or more MTJ elements may be laminated. For example, in a case where the n MTJ elements are laminated as n layers, the memory element may store the information on 2ⁿ values and the (2ⁿ−1) reference elements may be provided.

As described above, according to the determining device and the determining method, the higher the resistance value of the selected reference element, the higher the read voltage is increased. Thus, in a case of the high resistance with a high likelihood of the erroneous determination, the electric current difference may be increased between the reference element and the memory element, and the erroneous determination of the data may be kept from occurring. Furthermore, in a case of the low resistor with a low likelihood of the erroneous determination, the unintentional rewrite of the data stored in the memory element may be suppressed.

Furthermore, in a case of determining the data stored in the memory element, the determining unit may first select the lowest reference element of the multiple reference elements. Even though the read voltage is lower than a write voltage, the higher the voltage, the more likely the data stored in the memory element is to be rewritten. Moreover, there is a likelihood that the data is rewritten when applying a high write voltage in a state where electric current does not flow through the memory element. Therefore, the unintentional rewrite of the data stored in the memory element may be suppressed by performing a determination beginning with the lowest read voltage.

Furthermore, the determining device selects a reference element, different from the selected reference element, from the multiple reference elements, in a case where the data stored in the memory element is not able to be uniquely determined. Thus, the data stored in the memory element may be uniquely determined.

Furthermore, the determining device selects the reference element of which the reference value is the lowest, and which is different from the already-selected reference elements, from the multiple reference elements, in a case where the data stored in the memory element is not able to be uniquely determined. When the high read voltage is suddenly applied, there is a likelihood that the data stored in the memory element are rewritten. Therefore, the unintentional rewrite of the data stored in the memory element may be suppressed by performing the determination in the order of decreasing the read voltage.

Furthermore, the determining device may determine the read voltage corresponding to the reference element by rewriting the data in the memory element as a predetermined data and thus measuring the amount of electric current. For example, in a case where the read voltage is suitably applied while using the MRAM, the shape change of the device may be coped with at the time of manufacturing the MRAM and life of the device may be extended.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A determining device, comprising:
a memory element that includes laminated magnetoresistive elements;
a plurality of reference elements, each having a different resistance value;
a select circuit that selects a reference element from the plurality of reference elements;
an apply circuit that applies a higher read voltage selected from a plurality of different read voltages to the reference element selected by the select circuit and the memory element, as the resistance value of the reference element selected from the plurality of reference elements is higher;
a compare circuit that compares an amount of electric current flowing through the selected reference element to which the read voltage is applied by the apply circuit and an amount of electric current flowing through the memory element to which the read voltage is applied by the apply circuit; and
a determination circuit that determines data stored in the memory element, based on a result of comparison by the compare circuit.

2. The determining device according to claim 1,
wherein the select circuit selects the reference element of which the resistance value is the lowest, from the plurality of reference elements.

3. The determining device according to claim 1,
wherein the select circuit selects the reference element different from the selected reference element, from the plurality of reference elements, when the determination circuit is unable to uniquely determine the data stored in the memory element.

4. The determining device according to claim 3,
wherein the select circuit selects the reference element of which the resistance value is the lowest, and which is different from the selected reference elements, from the plurality of reference elements.

5. A determining method of determining data stored in a memory element that includes laminated magnetoresistive elements, comprising:
selecting a reference element from a plurality of reference elements, each having a different resistance value;
applying a higher read voltage selected from a plurality of different read voltages to the selected reference element and the memory element, as the resistance value of the selected reference element is higher;
comparing an amount of electric current flowing through the selected reference element to which the read voltage is applied and an amount of electric current flowing through the memory element to which the read voltage is applied; and
determining data stored in the memory element, based on a comparison result.

6. The determining method according to claim 5,
wherein the determining device writes a predetermined data in the memory element, applies a predetermined read voltage to the memory element, and updates the read voltage, based on the amount of electric current flowing through the memory element to which the predetermined read voltage is applied.
